(19) United States
(12) Patent Application Publication
(10) Pub. No.: US 2024/0222270 A1
(43) Pub. Date: Jul. 4, 2024

(54) VIA FUSE WITH METAL-INSULATOR-METAL ARCHITECTURE AND IMPROVED ELECTRODE MATERIAL

(71) Applicant: Intel Corporation, Santa Clara, CA (US)

(72) Inventor: Yao-Feng Chang, Bellemont, AZ (US)

(73) Assignee: Intel Corporation, Santa Clara, CA (US)

(21) Appl. No.: 18/148,147

(22) Filed: Dec. 29, 2022

(51) Int. Cl. H01L 23/525; H01L 21/768

(52) U.S. Cl. CPC H01L 23/5252; H01L 21/76886

(57) ABSTRACT

An apparatus comprising a device layer comprising a plurality of transistors; a first electrode; a second electrode over the first electrode; and a fuse material layer within a via, the via coupling the first and second electrodes together, wherein the fuse material layer is to conduct a non-zero current responsive to a first voltage between the first and second electrodes, and is to form an irreversible open circuit responsive to a second voltage between the first and second electrodes, wherein a magnitude of the second voltage is less than two volts.

### BACKGROUND

Integrated circuit (IC) devices may comprise one-time programmable (OTP) read-only memory (ROM) (sometimes referred to as PROM). Various product applications, such as reconfigurable ROM, root-of-trust implementations (memory redundancy), on-chip security keys, and unit-level-traceability rely on high-density OTP ROM that provides reliable, available, and affordable information storage. Electrical fuse (eFuse) and antifuse (AF) are the two of the most prevalent device technologies for implementing OTP ROM embedded within an IC device.

An electrical fuse is a sacrificial electrical device that initially provides a low electrical resistance/conductive path between two circuit nodes until an electrical current passed across the device exceeds a threshold level, which results in formation of a permanent/irreversible high resistance/non-conductive open circuit between the two circuit nodes. An antifuse is an electrical device that initially has a high resistance between two circuit nodes until a voltage across the device exceeds a certain level, resulting in a formation of a permanent/irreversible low resistance/conductive path between the two circuit nodes.

### BRIEF DESCRIPTION OF THE DRAWINGS

FIG. 1A is a top-down plan view of an example via fuse.

FIG. 1B is a cross-sectional view of the via fuse shown in FIG. 1A.

FIG. 1C is a circuit schematic associated with the via fuse of FIGS. 1A and 1B.

FIG. 2A is a cross-sectional view of the via fuse shown in FIG. 1B after application

of a programming voltage.

FIG. 2B is a circuit schematic associated with the via fuse of FIG. 2A.

FIG. 3A is an I-V graph of an example via fuse before and after programming.

FIG. 3B is an I-V graph of an example via fuse with an improved electrode material before and after programming.

FIG. 4 is a table illustrating example resistance and temperature characteristics of a via fuse for various thicknesses of an electrode material.

FIG. 5 is a flow diagram illustrating example methods of fabricating a via fuse.

FIGS. 6A, 6B, 6C and 6D are example cross-sectional views of an IC structure evolving as the methods illustrated in FIG. 5 are practiced.

FIGS. 7A and 7B are example cross-sectional views of an IC structure evolving as the methods illustrated in FIG. 5 are practiced.

FIGS. 8A and 8B are example cross-sectional views of an IC structure evolving as the methods illustrated in FIG. 5 are practiced.

FIG. 9 illustrates a mobile computing platform and a data server machine employing an IC with a via fuse, in accordance with any of the embodiments disclosed herein.

FIG. 10 is a top view of a wafer and dies that may include a via fuse, in accordance with any of the embodiments disclosed herein.

FIG. 11 is a cross-sectional side view of an integrated circuit device that may include a via fuse, in accordance with any of the embodiments disclosed herein.

FIGS. 12A-12D are perspective views of example planar, FinFET, gate-all-around, and stacked gate-all-around transistors.

FIG. 13 is a cross-sectional side view of an integrated circuit device assembly that may include a via fuse, in accordance with any of the embodiments disclosed herein.

FIG. 14 is a block diagram of an example electrical device that may include a via fuse, in accordance with any of the embodiments disclosed herein.

### DETAILED DESCRIPTION

Various embodiments of the present disclosure provide via fuses with metal-insulator-metal (MIM) architectures (referred to herein as via MIM fuses) and improved electrode materials. A via MIM fuse may irreversibly transition from an electrically conductive state where a relatively significant current can pass between two electrodes of the fuse to an electrical open state where only a nominal amount of current can pass between the two electrodes. In contrast to a conventional metal interconnect fuse, the via MIM fuse structures described herein comprise an electrically insulative fuse material layer between two electrodes, similar to an antifuse. However, in contrast to an antifuse, the insulative fuse material layer of the via MIM fuse structures described herein passes a relatively significant leakage current between the fuse electrodes at voltages below a programming voltage. In response to a higher voltage (e.g., a voltage exceeding a programming threshold), the leakage current induces an open circuit condition between the two fuse electrodes. This behavior contrasts with an antifuse response wherein in the absence of any significant leakage current, the insulative layer of the antifuse experiences dielectric breakdown at sufficiently high voltages leading to an electrical short condition.

As described further below, a high fuse density is possible by locating MIM fuses within interconnect via structures. Also, the via MIM fuses described herein may be based on capacitor MIM process modules integrated into back-end-of-line (BEOL) IC device interconnect fabrication. For example, an existing MIM capacitor fabrication process may be modified to integrate a via structure, in accordance with embodiments herein, and to alter the thickness and/or composition of the MIM insulator material layer and the MIM electrodes for an adequate leakage current and low programming voltage response. Indeed, use of improved materials (e.g., comprising ruthenium or molybdenum) for one or more of the electrodes of the via MIM fuse may result in ultra-low fuse programming voltages (e.g., <2V). As will also become apparent, a power-performance-area-cost (PPAC) metric for the via MIM fuses described herein can be superior to both metal fuse technology and MOS antifuse technology. Various embodiments of the via MIM fuses may provide area savings with respect to current metal fuse technologies without appreciably increasing circuit design complexity while also maintaining the low program voltages (e.g., <2.0V) used by metal fuses and avoiding the high program voltages utilized by antifuse technologies.

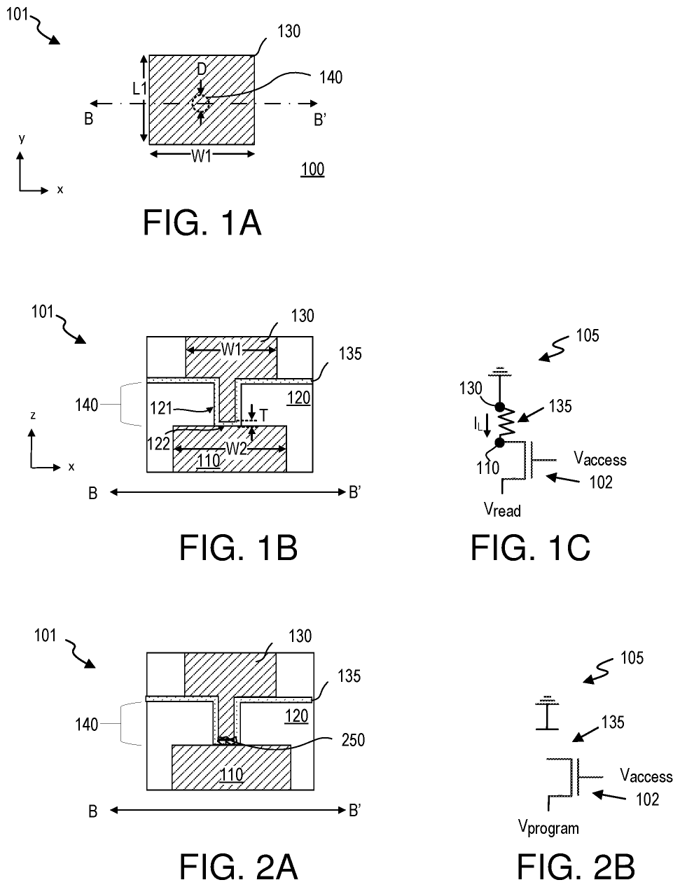

FIG. 1A is a top-down plan view of an example via metal-insulator-metal (MIM) fuse 101. As shown in FIG. 1A, an area of a substrate 100 is covered by a top fuse electrode 130 having a lateral electrode width W1 and lateral electrode length L1. Top fuse electrode 130 may be any electrically conductive material suitable for IC interconnects, capacitors, or other device contacts. In some embodiments, top fuse electrode 130 comprises polycrystalline silicon, graphite, or one or more metals, such as, but not limited to, copper, tungsten, nickel, cobalt, aluminum, molybdenum, ruthenium, platinum, or titanium. For embodiments in which the fuse electrode 130 is a metal, top fuse electrode 130 may be substantially one metal with only trace impurities. Alternatively, top fuse electrode 130 may include a plurality of metals layered in a stack structure or compositionally graded. Top fuse electrode 130 may also be a homogenous alloy of multiple metals, or comprise a grading of alloyed metals, etc. In some embodiments utilizing alloyed metal, the fuse electrode 130 may be a metallic compound, such as one or more of metal-nitrides, metal-carbides, or metal-silicides.

Top fuse electrode 130 is in electrical contact with an underlying via 140, drawn in dashed line in FIG. 1A to emphasize that via 140 is below a portion of the area of fuse electrode 130. Via 140 occupies a smaller area over the IC substrate associated with a bottom via diameter D. Although via area may vary with implementation, in some examples via area is less than 0.5 μm² ore even less than 0.2 μm² (in some embodiments the bottom via diameter D may be <0.5 μm).

FIG. 1B is a cross-sectional view of via MIM fuse 101 along the longitudinal B-B′ line illustrated in FIG. 1A. A corresponding fuse circuit schematic is also illustrated in FIG. 1C. As shown in the cross-sectional view, via 140 extends through a thickness (e.g., in the z-dimension) of a dielectric material 120. Dielectric material 120 may have any suitable chemical composition as embodiments are not limited in this respect. For example, dielectric material 120 may be silicon dioxide, silicon nitride, carbon-doped silicon dioxide, or other porous low-k materials known to be suitable for interlayer dielectric materials (ILD) found in the BEOL.

Via 140 is at least partially filled with metallization, and in the example illustrated, via metallization is contiguous with metallization of top fuse electrode 130, which is indicative of electrode metallization having been deposited into a via opening to form both the via 140 and the top fuse electrode 130. As further illustrated, via 140 further comprises a fuse material layer 135, which is between the overlying via (electrode) metallization and an underlying bottom fuse electrode 110. In the embodiment illustrated, fuse material layer 135 is in direct contact with bottom fuse electrode 110 at a via bottom 122. Fuse material layer 135 is also in direct contact with a sidewall 121 of dielectric material 120. Outside of the perimeter of via 140, fuse material layer 135 is also between a portion of top fuse electrode 130 and dielectric material 120.

The chemical composition of fuse material layer 135 may vary with implementation. In some embodiments, fuse material layer 135 is of a material that is more electrically insulative than either of bottom fuse electrode 110 or top fuse electrode 130. Fuse material layer 135 is therefore referred to herein as the insulator of a metal-insulator-metal (MIM) stack that further includes electrodes 110 and 130. In various embodiments, fuse material layer 135 may have a higher relative permittivity than dielectric material 120, for example. As an insulator, fuse material layer 135 may be a dielectric or a ferroelectric, etc.

In some advantageous embodiments, fuse material layer 135 is an oxide compound. In addition to comprising oxygen, fuse material layer 135 may comprise one or more of silicon, nitrogen, or a metal. In some embodiments, fuse material layer 135 is a metal oxide comprising predominantly oxygen and one or more metals. In some metal oxide embodiments, fuse material layer 135 is predominantly Hf and oxygen (e.g., HfO₂). In alternative embodiments, fuse material layer 135 is predominantly oxygen and at least one of Ti (e.g., TiO₂), Al (e.g., Al₂O₃), Zn (e.g., ZnO₂), W (e.g., WO3), Cu (e.g., CuO). In still other embodiments, fuse material layer 135 is predominantly silicon and at least one of oxygen or nitrogen (e.g., SiO₂ or Si₃N₄).

Regardless of composition, fuse material layer 135 is may have significantly lower electrical resistivity than would be suitable for an insulator of a charge storage capacitor. Insulator compositions with higher relative permittivity advantageously have lower electrical resistivity to ensure a leakage current IL through fuse material layer 135 is sufficient in the corresponding fuse circuit 105 depicted in FIG. 1C, which passes a relatively significant electrical current I_{L} at lower voltages (e.g., a read voltage V_{read} applied through access transistor 102) (thus fuse material 135 is shown as a resistor in fuse circuit 105). Current I_{L} is limited to the smallest via cross-sectional area (e.g., via bottom 122) since regions of electrodes 110 and 130 outside of via 140 are separated by a much greater thickness of dielectric material 120. Electrical resistance is a function of fuse material resistivity multiplied by the thickness of the material layer and divided by the area through which the current passes. The thickness T of fuse material layer 135 separating electrodes 110, 130 may thus be selected to provide a certain electrical resistance for a given via area (or via diameter D). A thinner fuse material layer 135 will advantageously provide a larger leakage current for a given voltage across electrodes 110, 130. For some exemplary embodiments where fuse material layer 135 is a metal oxide (e.g., HfO₂), fuse material layer thickness T is less than 10 nm (e.g., 5-9 nm), and may even be below 5 nm.

Bottom fuse electrode 110 may be any electrically conductive material suitable for IC interconnects, capacitors, or other device contacts. More specifically, bottom fuse electrode 110 may have any chemical composition suitable for a bottom electrode of any metal-insulator-metal capacitor. Bottom fuse electrode 110, may, for example, have any of the compositions described above for top fuse electrode 130. Bottom fuse electrode 110 may have the same composition as top fuse electrode 130, or bottom fuse electrode 110 may have a different composition than top fuse electrode 130.

As will be described in further detail below, in various embodiments of the present disclosure, the material and/or thickness of all or a portion of the bottom fuse electrode 110 and/or the top fuse electrode 130 may be selected so as to provide a desired programming voltage and/or temperature characteristics of the via MIM fuse 101. For example, at least a portion of the bottom fuse electrode 110 may be Ru or Mo (with allowances made for trace impurities) or may comprise Ru or Mo. In some embodiments, the majority of the bottom fuse electrode 110 (or a portion of the fuse electrode that is underneath via 140) is Ru or Mo. In some embodiments, a bottom portion of the bottom fuse electrode 110 may comprise a first material (e.g., predominately TiN or other suitable material) and a second layer of the bottom fuse electrode that is on top of the bottom portion may comprise a second material (e.g., predominately Ru or Mo). In some embodiments, the top electrode 130 may also (or alternatively) include a material that is predominately Ru or Mo.

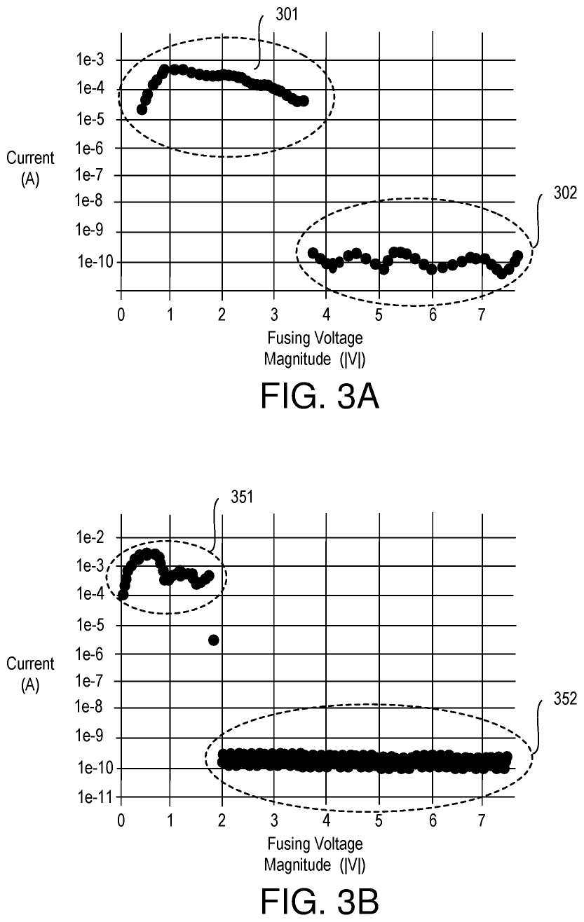

FIG. 2A is a cross-sectional view of the via MIM fuse 101 after a programming voltage has been applied (e.g., across the top and bottom electrode via, e.g., an access transistor 102) to the via MIM fuse. The corresponding open circuit state of fuse circuit 105 is illustrated in FIG. 2B. Because fuse material layer 135 passes current I_{L}, current-based phenomenological material degradation mechanisms can become significant at higher currents associated with a programming voltage V_{program}. Degradation of fuse material layer 135 may be associated with Joule heating (thermal) and/or electromigration (EM) mechanisms. Although not bound by theory, for some exemplary embodiments where fuse material layer 135 is a metal oxide (e.g., HfO₂), fuse material layer 135 may degrade through the migration of oxygen ions into one of the electrodes 110, 130 (depending on polarity of the programming voltage V_{program}). With such physical degradation mechanisms confined to via bottom 122, the physical degradation can rapidly accumulate into a void 250 within the portion of fuse material layer 135 occupying the area of via bottom 122. Within this small area, void 250 may, for example, span the entire fuse material layer thickness T. In practice, such voids may have an area nearly equal to, or larger than, the area of via bottom 122, inducing a large drop in electrical current between electrodes 110, 130. Accordingly, fuse material 135 is shown as an open circuit in fuse circuit 105.

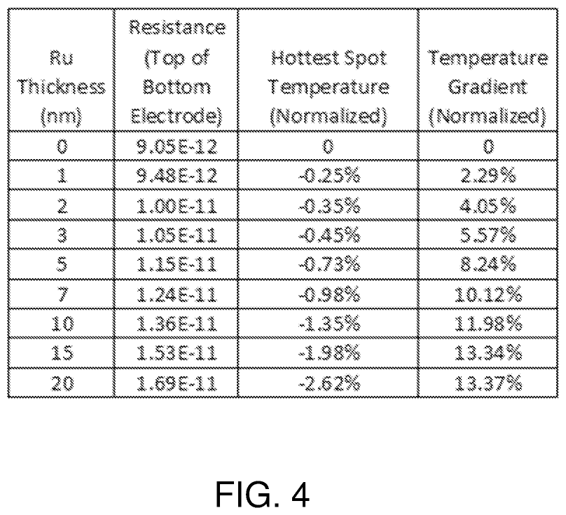

FIG. 3A is an I-V plot of a via MIM fuse with a bottom electrode comprising a first material (e.g., TiN) showing current through the fuse both before and after programming. In FIG. 3A, the magnitude of a direct current (DC) voltage applied between two fuse electrodes (e.g., 110, 130) and across the intervening fuse material insulator is plotted on the x-axis. A current measured between the two fuse electrodes is plotted on the y-axis. As shown, within a first fuse state (e.g., unprogrammed) 301, electrical current through the MIM via fuse initially is a substantially linear function of voltage, as expected for a resistor. From a maximum current of ˜1e-3 A, the current trends down even though voltage continues to increase until the current abruptly falls by approximately five orders of magnitude to ˜1e-10 A, or less. In a second fuse state (e.g., programmed) 302, there is no significant electrical current regardless of the applied voltage. Via MIM fusing induces the transition between states 301 and 302. In this example, the fuse programming voltage magnitude is around 3.5V. Notably, in this example the resistance ratio between the two fuse states 301, 302 is >10⁶, which is very competitive with alternative fuse and antifuse architectures.

FIG. 3B is an I-V plot of a via MIM fuse (e.g., 101) with a bottom electrode (e.g., 110) comprising a second material (e.g., Ru) showing current through the fuse both before and after programming. Again, the magnitude of a DC voltage applied between two fuse electrodes (e.g., 110, 130) and across the intervening fuse material insulator is plotted to the x-axis and a current measured between the two fuse electrodes is plotted to the y-axis. As shown, from a maximum current in between 1e-3 A and 1e-2 A in the first fuse state (e.g., unprogrammed) 351, the electrical current through the MIM via fuse drops by approximately six orders of magnitude to ˜1e-10 A in the second fuse state (e.g., programmed) 352. Again, in the second fuse state 352, there is no significant electrical current regardless of the applied voltage. In this example, the use of a different electrode material (e.g., Ru or Mo) and/or the thickness of the electrode results in the programming voltage magnitude being less than 1.9V (e.g., 1.86V). Again, the resistance ratio between the two fuse states 351 and 352 is quite high.

In various embodiments, the plots of FIGS. 3A and 3B may correspond to via MIM fuses having a fuse material layer comprising hafnium and oxygen, although other materials may result in similar plot characteristics.

The low programming voltage illustrated by FIG. 3B of the via MIM fuse is similar to programming voltages for some metal fuse technologies and is much lower than programming voltages for antifuse technologies. Accordingly, in some embodiments, via MIM fuses with low programming voltages enabled by electrodes comprising Ru or Mo may be adapted in place of metal fuse technologies without having to change the fuse programming voltage.

Ruthenium is a promising candidate for next generation interconnect material for BEOL-compatible process due to its low resistance to oxide, high melting-point, and low bulk resistivity. Molybdenum is another promising material for advanced BEOL processes. Thus, a fuse electrode (e.g., 110 and/or 130) comprising Ru or Mo may have high compatibility with BEOL processes. Such a fuse electrode may also allow a via MIM fuse to be programmed using a relatively low voltage (e.g., <2V). The electrode material and/or thickness may be selected based on corresponding resistance and/or temperature characteristics to provide a via MIM fuse with a low programming voltage.

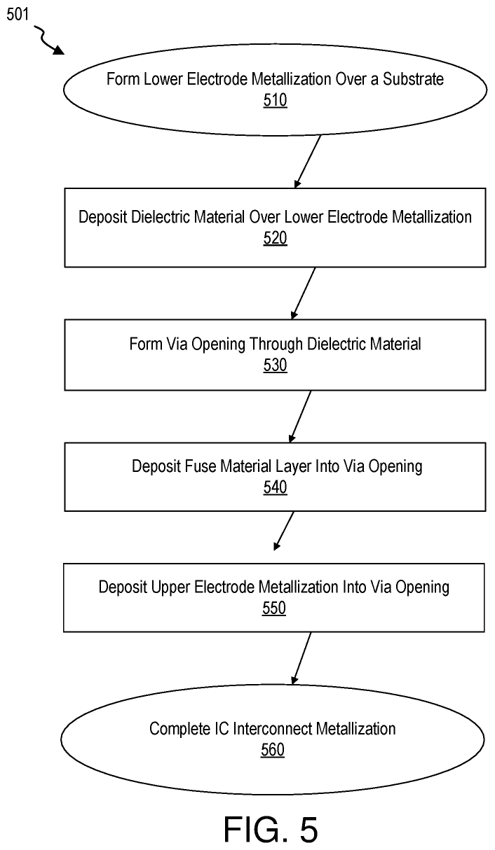

FIG. 4 is a table illustrating example resistance and temperature characteristics of a via MIM fuse for various thicknesses of a bottom electrode material. The results of FIG. 4 are based upon a thermal profile simulation of a via MIM fuse in which the thickness of Ru in a bottom electrode of a via MIM fuse is varied from 0 nm to 20 nm and the results are normalized against a via MIM fuse with a bottom electrode comprising TiN. In this simulation a layer of Ru with the specified thickness is added on top of the bottom electrode.

The added Ru to the TiN-based MIM via structure shows the expected resistance increasing and hottest spot temperature decreasing due to better thermal conductivity as compared to TiN (Ru thermal conductivity is around ˜120 W/(m*K); and TiN thermal conductivity is around 19 W/(m*K)). However, the hottest temperature degradation by Ru thickness is not very severe (within 3% even when the Ru thickness is increased to 20 nm). The major benefit to adding the Ru-based material in the MIM via structure is the temperature gradient, where the temperature gradient ranges from a ˜2% increase at an Ru thickness of 1 nm to ˜13% increase at an Ru thickness of 20 nm (again because thermal conductivity is higher in Ru-based materials.

Proper selection of the thickness of the Ru may result in a desired balance of programming voltage, hottest spot temperature, and temperature gradient. Based on the simulation results, an Ru thickness of between 5 and 10 nm results in a good balance between resistance, hottest spot temperature, and temperature gradient. An Ru thickness of ˜7 nm may result in the design with the best balance between hottest spot temperature and temperature gradient according to the thermal profile simulation. By decreasing the Ru thickness, the hottest spot temperature may be increased, but the temperature gradient is lower (and this situation could jeopardize provision of adequate temperature induced thermal stress on fusing site). By increasing the Ru thickness, the hottest temperature is lower, but the temperature gradient is higher (and this situation could jeopardize provision of adequate thermal-enhanced EM on fusing site).

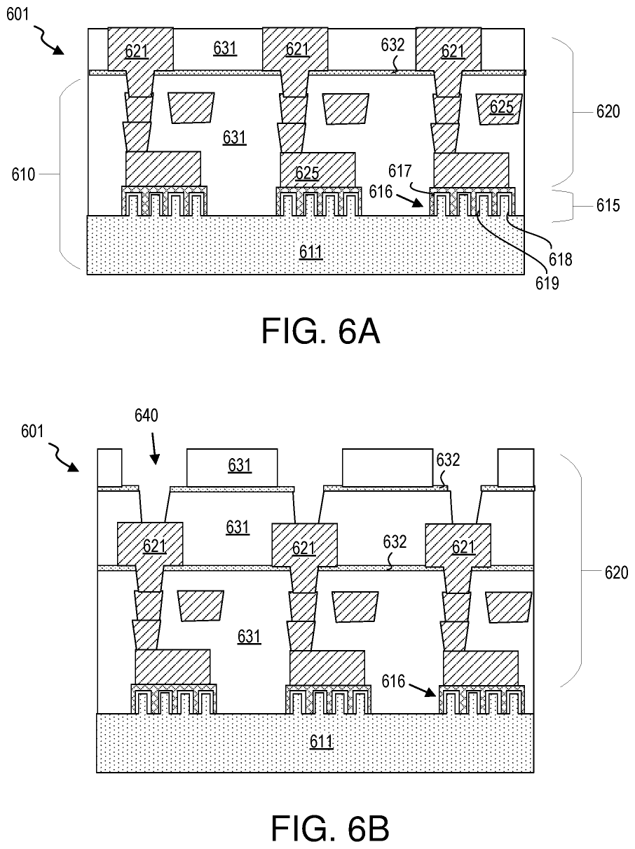

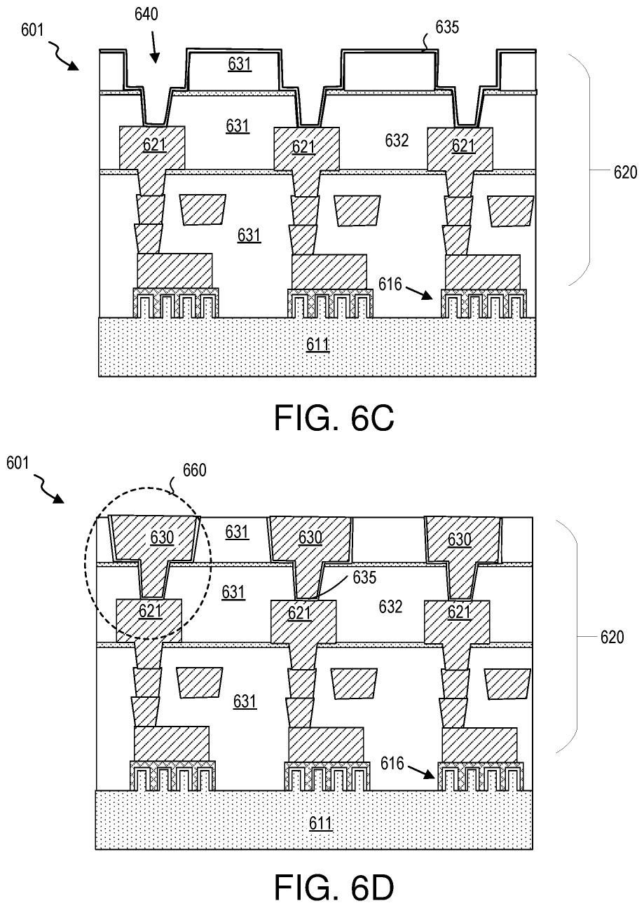

A via MIM fuse, as well as an IC incorporating such a fuse, may be fabricated according to a wide variety of techniques. FIG. 5 is a flow diagram illustrating some exemplary methods 501 for fabricating a via MIM fuse within interconnect metallization levels of an IC die. FIG. 6A-6D are cross-sectional views of an IC structure portion 601 evolving as the methods 501 are practiced in accordance with some embodiments. IC structures other than IC structure portion 601 may be fabricated according to methods 501. For example, MIM fuse 101 (FIG. 1A, 1B, 2A) may be fabricated according to methods 501. Similarly, IC structure portion 601 may be fabricated according to a method distinct from methods 501.

Referring first to FIG. 5, methods 501 begin at input 510 where first fuse electrode metallization is formed over an IC substrate. The IC substrate may include any base material known to be suitable for IC fabrication, such as a large format (e.g., 300-450 mm) wafer. One or more lithographic patterning processes may be performed at input 510. For example, a single or a double patterning process may be practiced to define first fuse electrode metallization of any suitable chemical composition and having any suitable lateral and vertical dimensions. In some embodiments, one or more damascene-type line or via formation processes comprising metal planarization are performed at input 510 based on the lithographic patterning process(es). In alternative embodiments, one or more subtractive line or via patterning process(es) are performed at input 510 based on the lithographic patterning process(es).

FIG. 6A further illustrates an exemplary IC structure portion 601 including first electrode metallization 621 over an IC substrate 610 comprising a base material 611. In some examples, base material 611 is substantially (mono)crystalline. Base material 611 may, for example, include one or more Group IV semiconductor material layers (e.g., Si, Ge, SiGe, GeSn, etc.), one or more Group III-V semiconductor material layers (e.g., InGaAs), one or more Group III-N semiconductor material layers (e.g., GaN), a combination of such semiconductor material layers, or other material (e.g., sapphire) known to be suitable as a workpiece substrate for IC device fabrication.

IC substrate 610 includes at least one device layer 615, each including one or more semiconductor materials. In some embodiments, device layer 615 may comprise planar, FinFET, gate-all-around, or stacked gate-all-around transistors, among other devices. In the illustrated example, device layer 615 comprises non-planar field effect transistors (FETs) 616. FETs 616 may be finFETs, nanoribbon or nanosheet FETs, nanowire FETs, stacked ribbon or wire FETs, etc. In the plane of FIG. 6A, a gate electrode 617 and a channel semiconductor 618 separated by a gate insulator 619 are visible. Although not shown, a source and drain may be coupled to opposite ends of channel semiconductor 618. Channel semiconductor 618 may comprise any suitable monocrystalline semiconductor material (e.g., silicon, Ge, SiGe, GeSn, etc.). Such FETs may be part of any suitable circuitry, such as an application specific IC (ASIC), for example.

IC substrate 610 further includes interconnect levels 620 comprising metallization features 625 that electrically interconnect devices (e.g., FETs 616, DRAM memory cells, RRAM memory cells, MRAM memory cells, etc.) of one or more device layers including device layer 615. In some embodiments, circuitry within IC structure portion 601 comprises a microprocessor core, further including an arithmetic logic unit (ALU) and shift registers, for example. In other examples, circuitry within IC structure portion 601 comprises a wireless radio circuit or floating-point gate array (FPGA).

As illustrated, fuse electrode metallization 621 is a subset of metallization features 625 and separate features of electrode metallization 621 are arrayed over an area of IC structure portion 601 within one of interconnect levels 620. Electrode metallization 621 may have the same composition as other metallization features 625 or may be of a distinct composition (e.g., specific to a fuse structure). Accordingly, electrode metallization 621 may comprise one or more of any conductive materials known to be suitable for IC interconnects or capacitor electrodes. In some embodiments, each of electrode metallization 621 comprises a metal, such as any of those described above. In various embodiments, electrode metallization 621 is predominantly Ru or Mo. In other embodiments, electrode metallization 621 is predominantly W, Co, Ti, or Pt. Electrode metallization 621 may be patterned according to subtractive or damascene techniques, with the latter being more suitable for embodiments where the chemical composition of electrode metallization 621 is not amenable to definition through etching processes.

In some embodiments, fuse electrode metallization 621 comprises a first layer of a first material (e.g., predominately metal other than Ru or Mo) and a second layer of a second material placed on top of at least a portion of the second layer. In various embodiments, the second layer is predominately Ru or Mo.

Interconnect levels 620 include one or more dielectric materials 631 and 632 surrounding metallization features 625. The chemical composition of dielectric materials 631 and 632 may be any composition known to be suitable as an IC device interlayer dielectric (ILD). In some embodiments, dielectric materials 631 and 632 comprise oxygen and may further comprise silicon (e.g., SiO₂, SiOC(H), SiON, etc.). Dielectric materials 631 and 632 may have any thickness (e.g., in z-dimension), as embodiments are not limited in this context.

Returning to FIG. 5, methods 501 continue at block 520 where a dielectric material is deposited over the first (lower) fuse electrode metallization. The dielectric material may be any suitable as an interlayer dielectric (ILD) for IC interconnects and may be deposited to any thickness suitable to provide electrical isolation to adjacent levels of metallization. At block 530, a via opening is formed through the dielectric material, exposing a portion of the lower electrode metallization. Any via patterning (e.g., lithography and etch) process(es) known to be suitable for forming interconnect vias through dielectric material of a particular composition may be practiced at block 530. In the example further illustrated in FIG. 6B, additional dielectric materials 631, 632 have been deposited over electrode metallization 621. An array of via openings 640 have been etched through the thickness of dielectric material 631, each of the via openings 640 exposing a portion of a corresponding feature of electrode metallization 621. In this example, each of the via openings 640 are formed as part of a dual-damascene interconnect structure that further comprises a trench opening of larger area than the via opening.

Returning to FIG. 5, methods 501 continue at block 540 where a fuse material layer is deposited into the via opening. In exemplary embodiments, a highly conformal deposition process is employed to precisely control the fuse material layer thickness. In some embodiments, a metal oxide is deposited with an atomic layer deposition (ALD) process employing a metal precursor (e.g., comprising Hf) and an oxygen precursor. Any number of ALD cycles may be performed, for example to form a fuse material layer 635 further depicted in FIG. 6C. In this exemplary embodiment, fuse material layer 635 has a substantially conformal thickness (e.g., less than 10 nm) and fully lines the dual-damascene structure.

Returning to FIG. 5, methods 501 continue at block 550 where another (upper) electrode metallization is deposited over the fuse material layer that is within the via opening. Electrode metallization may be deposited by any technique(s) known to be suitable for IC interconnect metallization and/or MIM capacitor electrode metallization. In some embodiments, a sputter deposition process and/or an electrolytic or electroless plating process is practiced at block 550. One or more metal may also be deposited by ALD. In some examples, multiple deposition processes are practiced at block 550, for example sputter-deposition of a seed layer may precede electrolytic plating of a fill metal. Methods 501 (FIG. 5) then end at output 560 where IC interconnect metallization is completed in any manner known to be suitable for IC device.

In the example illustrated in FIG. 6D, exemplary IC structure portion 601 further includes fuse electrode metallization 630, which substantially fills trenches and via openings within dielectric materials 631, 632. The array of via fuses 660 are then substantially complete, for example substantially as they may be found within an OTP ROM. Although not illustrated, any number of additional levels of interconnect metallization features may be formed over fuse electrode metallization 630. Following IC die singulation, packaging, and assembly into an electronic device, one or more of via fuses 660 may be programmed into an open circuit either in preparation for use in the field or during use in the field. Upon such programming, a void within fuse material 635 at the bottom of the via is formed in at least one of via fuses 660, for example substantially as illustrated for void 250 (FIG. 4).

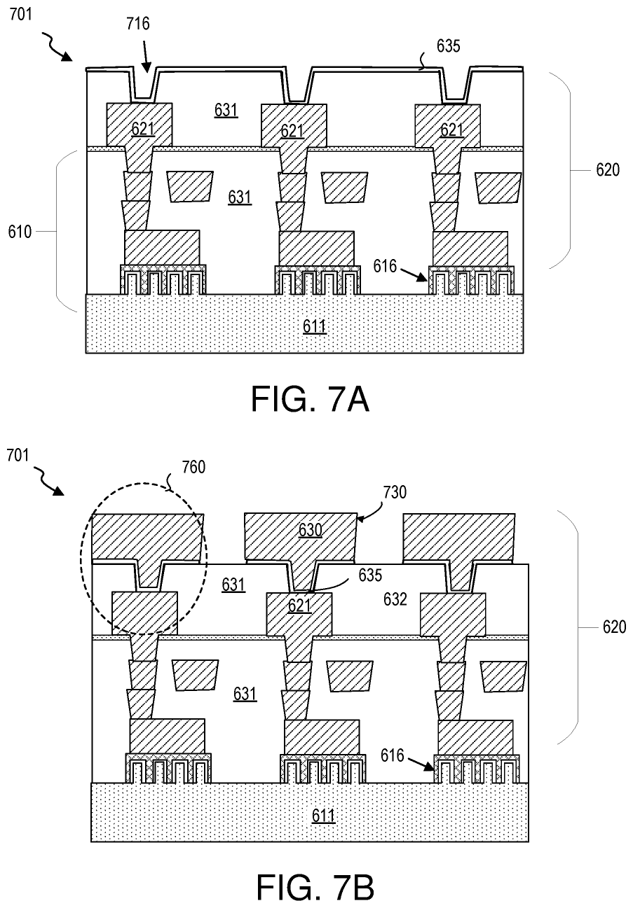

FIGS. 7A and 7B are cross-sectional views of an IC structure portion 701 evolving as the methods 501 are practiced in accordance with some alternative embodiments. In FIG. 7A, IC structure portion 701 includes fuse material layer 635 that has been deposited in a via opening 716 that is not part of a dual-damascene electrode metallization structure. As further illustrated in FIG. 7B, electrode metallization 630 again at least partially fills an upper portion of via opening 716, but electrode metallization 630 has been subtractively patterned to define electrode feature sidewall 730 and thereby complete fabrication of via MIM fuse 760. The etch process employed may be any suitable for the composition of electrode metallization 630 (e.g., W, Ru, Co, Mo, Ti or Pt). In the illustrated example, patterning on electrode metallization 630 also removes fuse material layer 635 from regions between adjacent features of electrode metallization 630. Alternatively, an etching of electrode metallization 630 may be sufficiently selective to stop on fuse material layer 635. Although not illustrated, additional dielectric material 631 may be subsequently deposited over electrode metallization 630 to complete fabrication of an IC device.

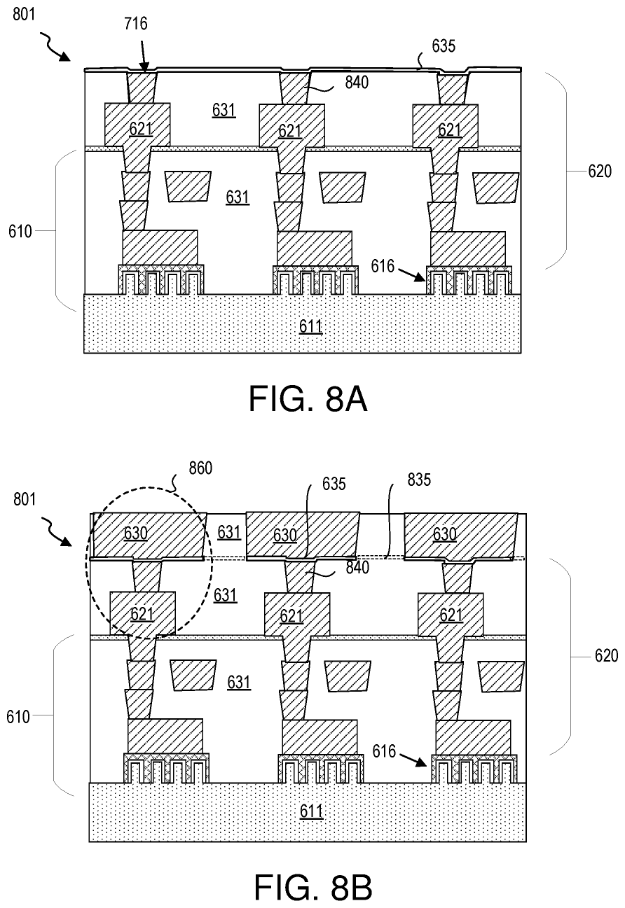

FIGS. 8A and 8B are cross-sectional views of an IC structure portion 801 evolving as the methods 501 are practiced in accordance with some alternative embodiments where a via MIM fuse includes fuse material at a top interface rather than a bottom interface of a via. As shown in FIG. 8A, a via 840 is formed after fabrication of fuse electrode metallization 621. In this example, via metallization 840 is in direct contact with electrode metallization 621. Via metallization 840 may have been fabricated according to any techniques known to be suitable for interconnect vias, such as, but not limited to, a metal deposition followed by planarization with surrounding dielectric material 631. Following the planarization process, fuse material layer 635 may be deposited, for example according to any of the techniques described elsewhere herein, or according to any technique known to be suitable for a material layer of a particular composition and thickness.

As illustrated in FIG. 8B, IC structure portion 801 further includes upper electrode metallization 630, completing via MIM fuse 860. In this example, electrode metallization 630 has been defined through a subtractive etch process that has also removed fuse material layer 635 from between adjacent fuses. However, as illustrated by dashed layer 835, fuse material layer 635 may remain continuous within an array of fuses if the electrode etch process stops upon fuse material layer 635. Alternatively, where electrode metallization 630 is instead patterned according to a single-damascene planarization process, fuse material layer 635 will be continuous between fuses within an array (e.g., substantially as represented by dashed line 835).

Any of the interconnect via MIM fuses described above may be implemented in any integrated circuit of any IC die. Such an IC die may include logic and/or memory, for example. The IC die may include both logic and memory, for example where a logic circuit, such as a processor further includes embedded DRAM (eDRAM). Any of the via MIM fuses described above may be implemented within one or more interconnect levels. For example, the IC structure portions described above may be implemented only within logic circuitry, only within memory array circuitry, or within both logic circuitry and memory array circuitry.

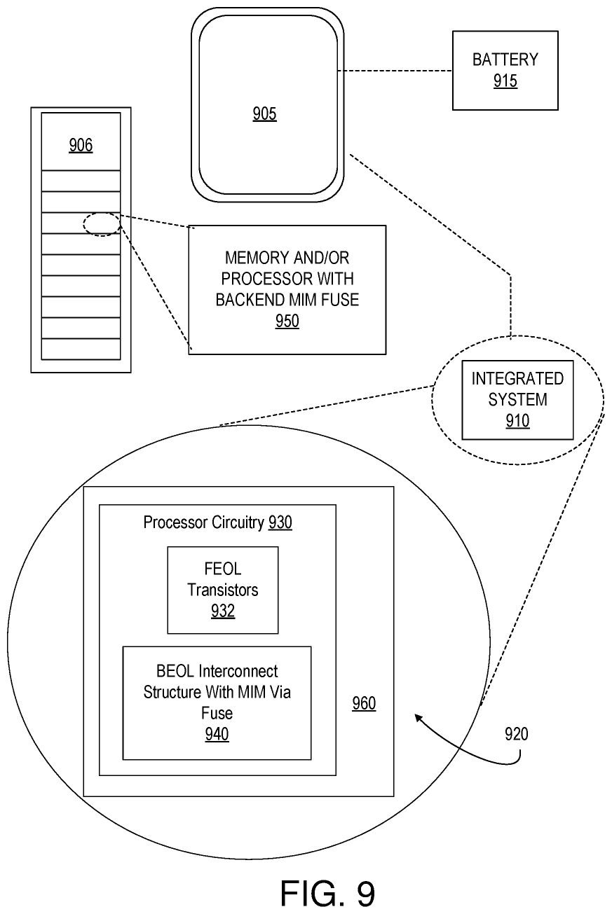

FIG. 9 illustrates a mobile computing platform 905 and a data server computing platform 906 employing an IC including a via MIM fuse as described herein (e.g., within an OTP ROM). The server platform 906 may be any commercial server, for example including any number of high-performance computing platforms disposed within a rack and networked together for electronic data processing, which in the exemplary embodiment includes a microprocessor 950 including a via MIM fuse as described herein (e.g., within an OTP ROM).

The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), a chip-level or package-level integrated system 910, and a battery 915. At least one IC of chip-level or package-level integrated system 910 includes a via MIM fuse as described herein (e.g., within an OTP ROM). In the example shown in expanded view 920, integrated system 910 includes microprocessor circuitry 930 including FEOL transistors 932 and BEOL interconnect fuse structures 940. In exemplary embodiments interconnect fuse structures 940 include a via MIM fuse as described herein (e.g., within an OTP ROM).

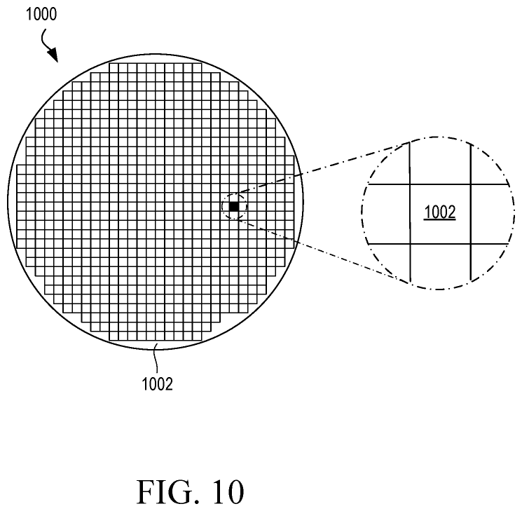

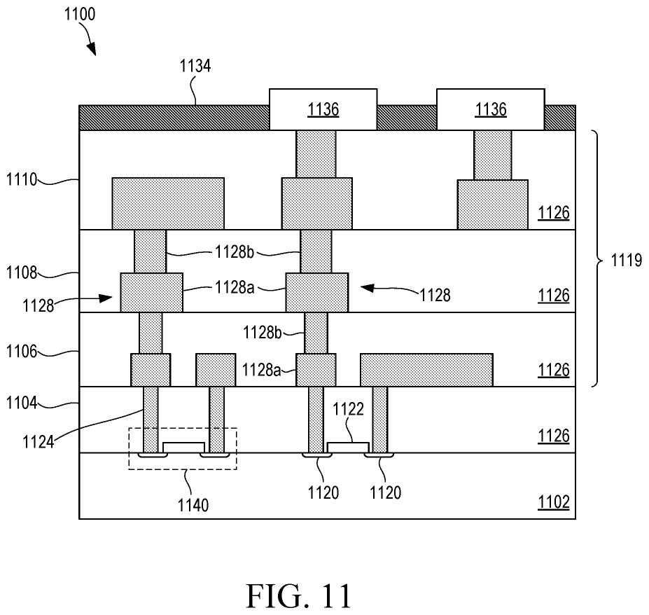

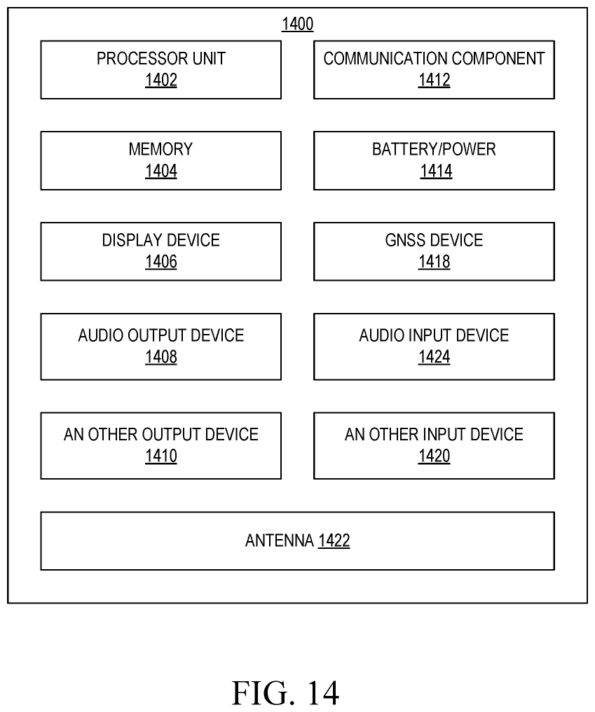

FIG. 10 is a top view of a wafer 1000 and dies 1002 wherein individual dies may include a via MIM fuse as described herein (e.g., within an OTP ROM). The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the semiconductor product is complete, the wafer 1000 may undergo a singulation process in which the dies 1002 are separated from one another to provide discrete “chips” of the integrated circuit product. The die 1002 may include one or more transistors (e.g., some of the transistors 1140 of FIG. 11, discussed below), supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, OTP RAM, etc.), a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1402 of FIG. 14) or other logic that is configured to store information in the memory devices or execute instructions stored in the memory array.

FIG. 11 is a cross-sectional side view of an integrated circuit device 1100 that may include a via MIM fuse as described herein (e.g., within an OTP ROM). Characteristics of the integrated circuit device 1100 may also be applicable to IC structure portions 601, 701, 801 where appropriate. One or more of the integrated circuit devices 1100 may be included in one or more dies 1002 (FIG. 10). The integrated circuit device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 1002 of FIG. 10) or a wafer (e.g., the wafer 1000 of FIG. 10).

The integrated circuit device 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

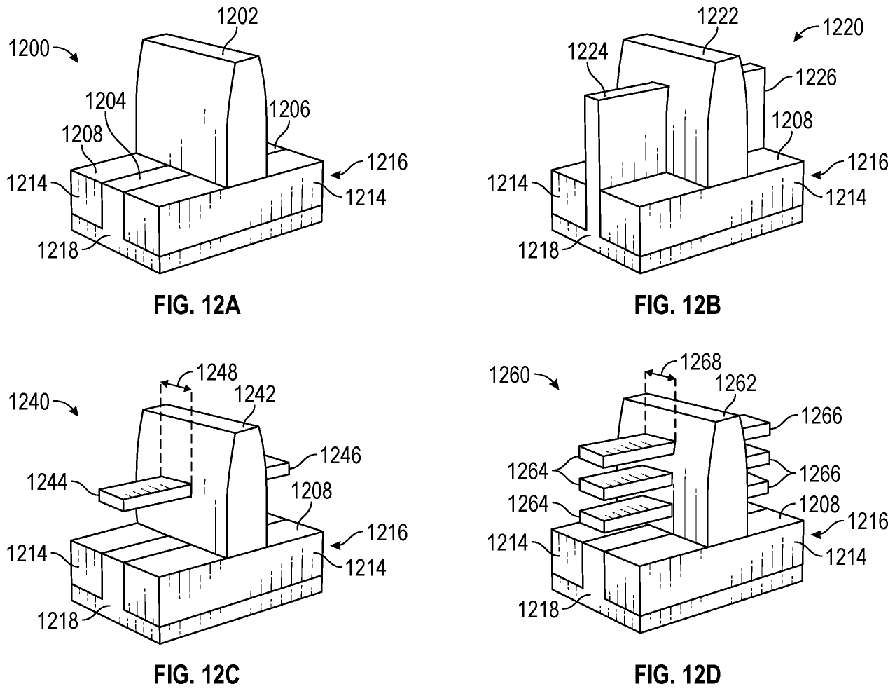

FIGS. 12A-12D are simplified perspective views of example planar, FinFET, gate-all-around, and stacked gate-all-around transistors. The transistors illustrated in FIGS. 12A-12D are formed on a substrate 1216 having a surface 1208. Isolation regions 1214 separate the source and drain regions of the transistors from other transistors and from a bulk region 1218 of the substrate 1216.

FIG. 12A is a perspective view of an example planar transistor 1200 comprising a gate 1202 that controls current flow between a source region 1204 and a drain region 1206. The transistor 1200 is planar in that the source region 1204 and the drain region 1206 are planar with respect to the substrate surface 1208.

FIG. 12B is a perspective view of an example FinFET transistor 1220 comprising a gate 1222 that controls current flow between a source region 1224 and a drain region 1226. The transistor 1220 is non-planar in that the source region 1224 and the drain region 1226 comprise “fins” that extend upwards from the substrate surface 1228. As the gate 1222 encompasses three sides of the semiconductor fin that extends from the source region 1224 to the drain region 1226, the transistor 1220 can be considered a tri-gate transistor. FIG. 12B illustrates one S/D fin extending through the gate 1222, but multiple S/D fins can extend through the gate of a FinFET transistor.

FIG. 12C is a perspective view of a gate-all-around (GAA) transistor 1240 comprising a gate 1242 that controls current flow between a source region 1244 and a drain region 1246. The transistor 1240 is non-planar in that the source region 1244 and the drain region 1246 are elevated from the substrate surface 1228.

FIG. 12D is a perspective view of a GAA transistor 1260 comprising a gate 1262 that controls current flow between multiple elevated source regions 1264 and multiple elevated drain regions 1266. The transistor 1260 is a stacked GAA transistor as the gate controls the flow of current between multiple elevated S/D regions stacked on top of each other. The transistors 1240 and 1260 are considered gate-all-around transistors as the gates encompass all sides of the semiconductor portions that extends from the source regions to the drain regions. The transistors 1240 and 1260 can alternatively be referred to as nanowire, nanosheet, or nanoribbon transistors depending on the width (e.g., widths 1248 and 1268 of transistors 1240 and 1260, respectively) of the semiconductor portions extending through the gate.

Returning to FIG. 11, a transistor 1140 may include a gate 1122 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together. In various embodiments, a via MIM fuse may be integrated within a via 1128b.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (e.g., farther away from the device layer 1104) may be thicker that the interconnect layers that are lower in the metallization stack 1119, with lines 1128a and vias 1128b in the higher interconnect layers being thicker than those in the lower interconnect layers.

In various embodiments, a via MIM fuse may be formed between a fourth interconnect layer (referred to as Metal 4 or “M3”) that is formed above the third interconnect layer and the second interconnect layer. In some embodiments, a fuse material layer may be placed under a via between the fourth interconnect layer and the second interconnect layer.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board). The integrated circuit device 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. In some embodiments, TSVs extending through the substrate can be used for routing power and ground signals from conductive contacts on the opposite side of the integrated circuit device 1100 from the conductive contacts 1136 to the transistors 1140 and any other components integrated into the die 1100, and the metallization stack 1119 can be used to route I/O signals from the conductive contacts 1136 to transistors 1140 and any other components integrated into the die 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

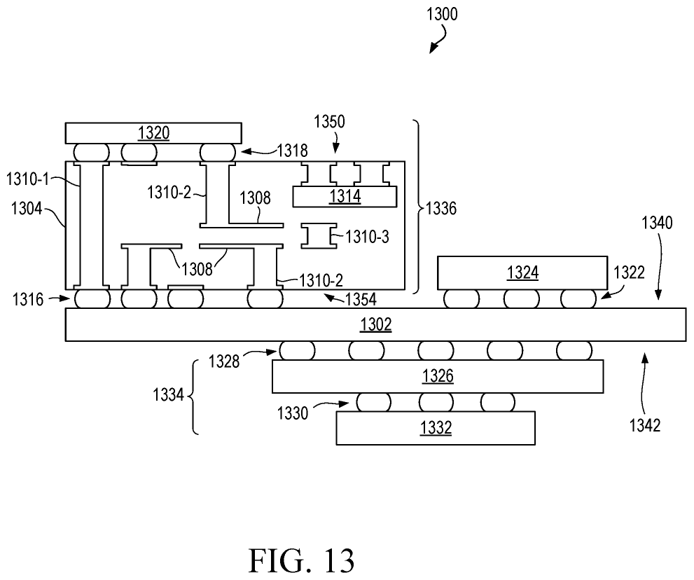

FIG. 13 is a cross-sectional side view of an integrated circuit device assembly 1300. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpacked integrated circuit product that includes one or more integrated circuit dies (e.g., a die including IC structure portion 601, 701, or 801, the die 1002 of FIG. 10, the integrated circuit device 1100 of FIG. 11, etc.) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder bumps attached to contacts on the die. The solder bumps allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of the via MIM fuses disclosed herein. For example, any suitable ones of the components of the electrical device 1400 may include one or more of the integrated circuit device assemblies 1300, integrated circuit components 1320, integrated circuit devices 1100, or integrated circuit dies 1002 disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards mainboards, or system boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include an other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include an other input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag. Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal.

The terms “substantially.” “close.” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features.

Example 1 includes an apparatus, comprising a device layer comprising a plurality of transistors; a first electrode; a second electrode over the first electrode; and a fuse material layer within a via, the via coupling the first and second electrodes together, wherein the fuse material layer is to conduct a non-zero current responsive to a first voltage between the first and second electrodes, and is to form an irreversible open circuit responsive to a second voltage between the first and second electrodes, wherein a magnitude of the second voltage is less than two volts.

Example 2 includes the subject matter of Example 1, and wherein the first electrode comprises a layer comprising ruthenium.

Example 3 includes the subject matter of any of Examples 1 and 2, and wherein the layer comprising ruthenium is between 5 and 10 nanometers thick.

Example 4 includes the subject matter of any of Examples 1-3, and wherein the first electrode comprises molybdenum.

Example 5 includes the subject matter of any of Examples 1-4, and wherein the first electrode comprises a first layer over a second layer, wherein the first layer comprises at least one of ruthenium or molybdenum and wherein the second layer comprises a conductive metal other than ruthenium and molybdenum.

Example 6 includes the subject matter of any of Examples 1-5, and wherein the conductive metal is titanium.

Example 7 includes the subject matter of any of Examples 1-6, and wherein the fuse material layer comprises predominately a metal and oxygen.

Example 8 includes the subject matter of any of Examples 1-7, and wherein the fuse material layer comprises hafnium and oxygen.

Example 9 includes the subject matter of any of Examples 1-8, and wherein one or more of the first electrode and the second electrode comprises one or more of ruthenium or molybdenum.

Example 10 includes the subject matter of any of Examples 1-9, and further including an integrated circuit die comprising the device layer, first and second electrodes, and fuse material layer.

Example 11 includes the subject matter of any of Examples 1-10, and further including a circuit board coupled to the integrated circuit die.

Example 12 includes the subject matter of any of Examples 1-11, and further including at least one of a network interface, battery, or memory coupled to the integrated circuit die.

Example 13 includes an apparatus comprising a device layer comprising a plurality of transistors; a plurality of programmable fuses, individual fuses of the plurality of programmable fuses comprising a first metallization feature; a second metallization feature over the first metallization feature; and a fuse material layer within a via, the via coupling the first and second metallization features together, wherein at least one of the first and second metallization features comprise at least one of ruthenium or molybdenum.

Example 14 includes the subject matter of Example 13, and wherein the fuse material layer is to conduct a non-zero current responsive to a first voltage between the first and second metallization features, and is to form an irreversible open circuit responsive to a second voltage between the first and second metallization features.

Example 15 includes the subject matter of any of Examples 13 and 14, and wherein a magnitude of the second voltage is less than two volts.

Example 16 includes the subject matter of any of Examples 13-15, and wherein a layer of the first metallization feature that comprises at least one of ruthenium or molybdenum has a thickness of between 5 and 10 nanometers.

Example 17 includes the subject matter of any of Examples 13-16, and wherein the first metallization feature comprises a layer comprising ruthenium.

Example 18 includes the subject matter of any of Examples 13-17, and wherein the layer comprising ruthenium is between 5 and 10 nanometers thick.

Example 19 includes the subject matter of any of Examples 13-18, and wherein the first metallization feature comprises molybdenum.

Example 20 includes the subject matter of any of Examples 13-19, and wherein the first metallization feature comprises a first layer over a second layer, wherein the first layer comprises at least one of ruthenium or molybdenum and wherein the second layer comprises a conductive metal other than ruthenium and molybdenum.

Example 21 includes the subject matter of any of Examples 13-20, and wherein the conductive metal is titanium.

Example 22 includes the subject matter of any of Examples 13-21, and wherein the fuse material layer comprises predominately a metal and oxygen.

Example 23 includes the subject matter of any of Examples 13-22, and wherein the fuse material layer comprises hafnium and oxygen.

Example 24 includes the subject matter of any of Examples 13-23, and further including an integrated circuit die comprising the device layer, first and second metallization features, and fuse material layer.

Example 25 includes the subject matter of any of Examples 13-24, and further including a circuit board coupled to the integrated circuit die.

Example 26 includes the subject matter of any of Examples 13-25, and further including at least one of a network interface, battery, or memory coupled to the integrated circuit die.

Example 27 includes a method comprising forming a device layer comprising a plurality of transistors; and forming a via metal-insulator-metal (MIM) fuse over the plurality of transistors, wherein a via MIM fuse includes a bottom electrode, a top electrode, and a fuse material within a via coupling the top electrode to the bottom electrode, wherein the via MIM fuse is programmable by a voltage having a magnitude less than two volts.

Example 28 includes the subject matter of Example 27, and wherein forming the via MIM fuse comprises forming the bottom electrode by depositing at least one of ruthenium or molybdenum.

Example 29 includes the subject matter of any of Examples 27 and 28, and wherein depositing at least one of ruthenium or molybdenum comprises depositing a layer comprising at least one of ruthenium or molybdenum to a thickness of between 5 and 10 nanometers.

Example 30 includes the subject matter of any of Examples 27-29, and further including depositing the layer comprising at least one of ruthenium or molybdenum over another layer of the bottom electrode.

Example 31 includes the subject matter of any of Examples 27-30, and wherein the bottom electrode comprises a layer comprising ruthenium.

Example 32 includes the subject matter of any of Examples 27-31, and wherein the layer comprising ruthenium is between 5 and 10 nanometers thick.

Example 33 includes the subject matter of any of Examples 27-32, and wherein the bottom electrode comprises molybdenum.

Example 34 includes the subject matter of any of Examples 27-33, and wherein the bottom electrode comprises a first layer over a second layer, wherein the first layer comprises at least one of ruthenium or molybdenum and wherein the second layer comprises a conductive metal other than ruthenium and molybdenum.

Example 35 includes the subject matter of any of Examples 27-34, and wherein the conductive metal is titanium.

Example 36 includes the subject matter of any of Examples 27-35, and wherein the fuse material comprises predominately a metal and oxygen.

Example 37 includes the subject matter of any of Examples 27-36, and wherein the fuse material comprises hafnium and oxygen.

Example 38 includes the subject matter of any of Examples 27-37, and wherein one or more of the bottom electrode and the top electrode comprises one or more of ruthenium or molybdenum.

Example 39 includes the subject matter of any of Examples 27-38, and further including forming an integrated circuit die comprising the plurality of transistors, top and bottom electrodes, and fuse material.

Example 40 includes the subject matter of any of Examples 27-39, and further including coupling a circuit board to the integrated circuit die.

Example 41 includes the subject matter of any of Examples 27-40, and further including coupling at least one of a network interface, battery, or memory to the integrated circuit die.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus, comprising:
a device layer comprising a plurality of transistors;
a first electrode;
a second electrode over the first electrode; and
a fuse material layer within a via, the via coupling the first and second electrodes together, wherein the fuse material layer is to conduct a non-zero current responsive to a first voltage between the first and second electrodes, and is to form an irreversible open circuit responsive to a second voltage between the first and second electrodes, wherein a magnitude of the second voltage is less than two volts.

2. The apparatus of claim 1, wherein the first electrode comprises a layer comprising ruthenium.

3. The apparatus of claim 2, wherein the layer comprising ruthenium is between 5 and 10 nanometers thick.

4. The apparatus of claim 1, wherein the first electrode comprises molybdenum.

5. The apparatus of claim 1, wherein the first electrode comprises a first layer over a second layer, wherein the first layer comprises at least one of ruthenium or molybdenum and wherein the second layer comprises a conductive metal other than ruthenium and molybdenum.

6. The apparatus of claim 5, wherein the conductive metal is titanium.

7. The apparatus of claim 1, wherein the fuse material layer comprises predominately a metal and oxygen.

8. The apparatus of claim 1, wherein the fuse material layer comprises hafnium and oxygen.

9. The apparatus of claim 1, wherein one or more of the first electrode and the second electrode comprises one or more of ruthenium or molybdenum.

10. The apparatus of claim 1, further comprising an integrated circuit die comprising the device layer, first and second electrodes, and fuse material layer.

11. The apparatus of claim 10, further comprising a circuit board coupled to the integrated circuit die.

12. The apparatus of claim 10, further comprising at least one of a network interface, battery, or memory coupled to the integrated circuit die.

13. An apparatus comprising:
a device layer comprising a plurality of transistors;
a plurality of programmable fuses, individual fuses of the plurality of programmable fuses comprising:
a first metallization feature;
a second metallization feature over the first metallization feature; and
a fuse material layer within a via, the via coupling the first and second metallization features together, wherein at least one of the first and second metallization features comprise at least one of ruthenium or molybdenum.

14. The apparatus of claim 13, wherein the fuse material layer is to conduct a non-zero current responsive to a first voltage between the first and second metallization features, and is to form an irreversible open circuit responsive to a second voltage between the first and second metallization features.

15. The apparatus of claim 14, wherein a magnitude of the second voltage is less than two volts.

16. The apparatus of claim 13, wherein a layer of the first metallization feature that comprises at least one of ruthenium or molybdenum has a thickness of between 5 and 10 nanometers.

17. A method comprising:
forming a device layer comprising a plurality of transistors; and
forming a via metal-insulator-metal (MIM) fuse over the device layer, wherein a via MIM fuse includes a bottom electrode, a top electrode, and a fuse material within a via coupling the top electrode to the bottom electrode, wherein the via MIM fuse is programmable by a voltage having a magnitude less than two volts.

18. The method of claim 17, wherein forming the via MIM fuse comprises forming the bottom electrode by depositing at least one of ruthenium or molybdenum.

19. The method of claim 18, wherein depositing at least one of ruthenium or molybdenum comprises depositing a layer comprising at least one of ruthenium or molybdenum to a thickness of between 5 and 10 nanometers.

20. The method of claim 19, further comprising depositing the layer comprising at least one of ruthenium or molybdenum over another layer of the bottom electrode.
